(19) United States
(12) Patent Application Publication
(10) Pub. No.: US 2020/0146167 A1
(43) Pub. Date: May 7, 2020

(54) De-Centralized Electronic System

(71) Applicant: Chris Manouel, Garland, TX (US)

(72) Inventor: Chris Manouel, Garland, TX (US)

(21) Appl. No.: 16/183,412

(22) Filed: Nov. 7, 2018

(51) Int. Cl. H05K 7/14; H05K 7/18; H04N 5/655

(52) U.S. Cl. CPC H05K 7/1457; H05K 7/186; H04N 5/655; H05K 7/1452; H05K 7/1417

(57) ABSTRACT

A system and method for a de-centralized electronic system. The de-centralized electronic system includes at least one flat rack which has a plurality of holes. The holes are used to couple on or more clips. The clips, in conjunction with a coupling device, secure a device, such as a controller, to the flat back. In this fashion, one or more controllers can be secured to a flat rack. The flat rack can be secured behind a television set to secure and hide controllers.

### PRIORITY

The present invention claims priority to provisional application No. 62/555,120 filed Sep. 7, 2017, the entirety of which is hereby incorporated by reference.

### BACKGROUND OF THE INVENTION

### Technical Field

The present invention relates to a system and method for a de-centralized electronic system.

### Description of Related Art

Traditionally, multimedia and home security or electronics were stored in a central server rack. The information was then spread about the house to each of the remote devices such as speakers, televisions, etc. Consequently, there is a need for a de-centralized electronic system.

### BRIEF DESCRIPTION OF THE DRAWINGS

The novel features believed characteristic of the invention are set forth in the appended claims. The invention itself, however, as well as a preferred mode of use, further objectives and advantages thereof, will be best understood by reference to the following detailed description of illustrative embodiments when read in conjunction with the accompanying drawings, wherein:

FIG. 1 is a schematic of a centralized electronic system;

FIG. 2 is a perspective view of a de-centralized system in one embodiment;

FIG. 3 is a perspective view of a de-centralized system in one embodiment;

FIG. 4 is a perspective view of a clip in one embodiment;

FIG. 5 is a perspective view of a de-centralized system in one embodiment;

FIG. 6 is a perspective view of an extender in one embodiment;

FIG. 7 is a perspective view of the aggregator in one embodiment;

FIG. 8 is a front view of a user interface in one embodiment.

### DETAILED DESCRIPTION

Several embodiments of Applicant's invention will now be described with reference to the drawings. Unless otherwise noted, like elements will be identified by identical numbers throughout all figures. The invention illustratively disclosed herein suitably may be practiced in the absence of any element which is not specifically disclosed herein.

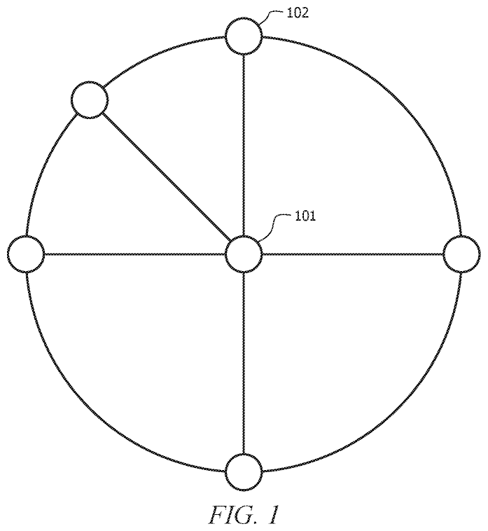

FIG. 1 is a schematic of a centralized electronic system. In the embodiment shown the server rack 101 is centralized. It houses most of the electronic receivers, amplifiers, controllers, cable boxes, DVD players, etc., referred to as controllers 106, which operate the electronic devices 102. The electronic devices 102 can comprise virtually any residential or commercial building. The devices 102 can include audio video equipment, security equipment, smart home equipment such as Smart Thermostats, and other such equipment. Previously, the server rack 101 was stored in a centralized location such as a closet. Wires were then routed from the centralized location to the remote locations for each electronic device 102. However, due to the novel system discussed herein, the system can be de-centralized. Thus, a controller 106 is any device which provides an input signal for display or reproduction, such as audio, video, or data.

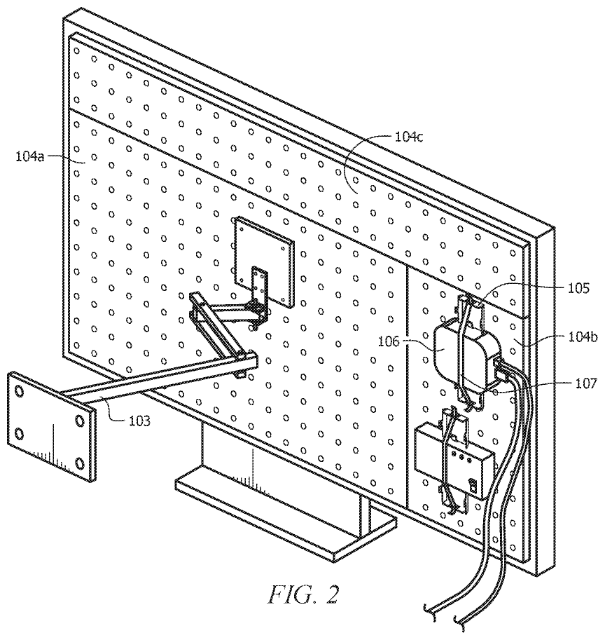

FIG. 2 is a perspective view of a de-centralized system in one embodiment. As depicted the system is shown for use on a television. This is for illustrative purposes only and should not be deemed limiting. The system can be used on virtually any electronic device.

As shown the flat rack 104 is coupled downstream to a mount 103. As used herein downstream and upstream refer to locations relative to a wall. A mount 103 is downstream of the wall but is upstream of the flat rack 104. The mount 103 can comprise any mount known in the art.

The mount 103 mounts to the flat rack 104. It can be mounted via any method or device known in the art including screws, bolts, etc.

The flat rack 104, in one embodiment, comprises a planar piece which has a plurality of holes. These holes allow controllers 106 to be coupled and housed along the flat rack 104. The flat rack can comprise virtually any material including metal, wood, rubber, plastic, polymers, and combinations thereof.

As depicted the flat rack 104 comprises a central portion 104a and extender portions. In one embodiment the flat rack 104 comprises a plurality of modular pieces which can be added and removed. The adjacent pieces can be joined in any method or device known in the art including screws, bolts, etc. As shown, an upper portion 104c has been added to the central portion 104a. Likewise, a right portion 104b has also been added to the central portion 104a. In this fashion, the size of the flat rack 104 can be adjusted to account for the varying size of the electronic device 102, such as a TV. As an example, in one embodiment the central portion 104a of the flat rack 104 is sized to match a 40 inch television. If a 60 inch television is used, then the portions can be added or removed as necessary to obtain the desired dimensions.

The television would be coupled downstream of the flat rack 104. In one embodiment the television, or other electronic device 102, is coupled to the mount as it would have been previously. The difference is that between the mount 103 and the television is the flat rack 104.

As shown the flat rack 104 has a plurality of controllers 106 attached thereto. Because controllers 106 are decreasing in size, weight, and dimensions, rather than being stored in a centralized location, such as a closet, these controllers 106 can be housed behind or adjacent to the electronic device 102, such as a television. This was previously not possible. The flat rack 104, and the system discussed herein, allows the controllers 106 to be safely and securely housed at the remote location.

As depicted the controllers 106 are coupled to the flat rack 104 via coupling device 107. The coupling device 107 can comprise straps, zip ties, cordage, etc. The coupling device 107 is coupled to the flat rack 104 and safely secures the controller 106 to the flat rack 104.

In the embodiment depicted, the coupling device 107 is coupled to a clip 105, discussed in more detail below. The clip 105 secures to the flat rack 104 via at least one hole located in the flat rack 104.

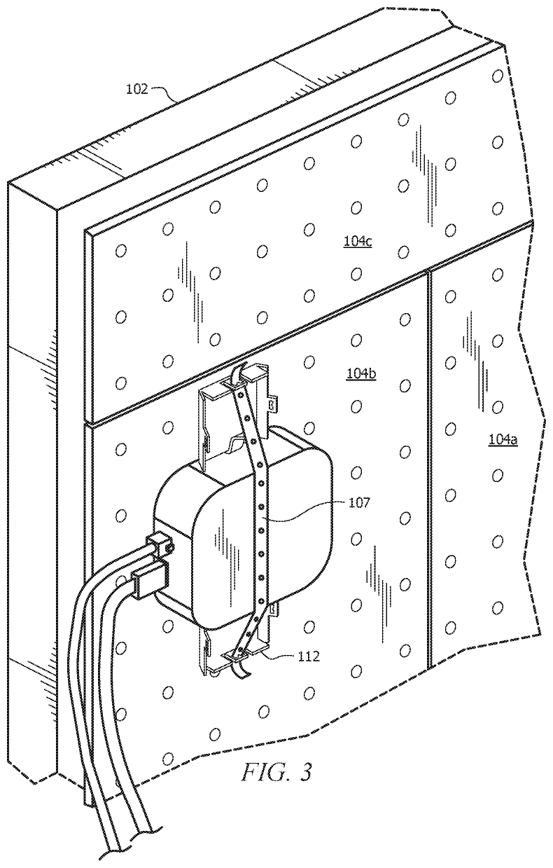

FIG. 3 is a perspective view of a de-centralized system in one embodiment. FIG. 3 shows one example wherein the coupling device 107 comprises a plurality of holes. In one embodiment the clip 105 comprises a male end which couples with one of the holes in the coupling device 107. This allows the installer to tighten the coupling device 107 securely around the controller 106.

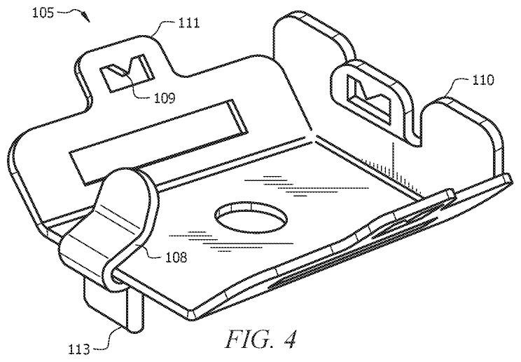

FIG. 4 is a perspective view of a clip in one embodiment. Many types of clips can be utilized, and the illustrated embodiment is for illustrative purposes only and should not be deemed limiting. The clip 105 illustrated offers a multitude of ways in which the coupling device 107 can be coupled to the clip 105. Receiving a plurality of coupling devices increases in the flexibility and versatility of the clip 105. If an installer has zip ties, then they can use this clip 105. Likewise, if an installer has a coupling device similar to that shown in FIG. 3, that installer can also use this clip 105.

The clip 105 can be coupled to the flat back 104 via any method or device known in the art. In one embodiment the clip 105 comprises one or more legs 113 which are inserted into the holes located on the flat back 104. In one embodiment the legs 113 extend downward beyond the planar face of the clip and which engage the holes on the flat rack 104. In on embodiment the legs comprise a longitudinal extension which is approximately perpendicular to the length of the leg 113 which will engage the hole of the flat back 104. In one embodiment the clip 105 has one leg, but in other embodiments the clip 105 has two or more legs. In still other embodiments a connecting device can be inserted into the clip 105 which secures with one of the holes on the flat back 104.

As depicted the clip 105 can receive cable-ties through the cable-tie acceptor 109. The cable-tie acceptor 109 has a tongue 111 which engages with the cable-tie. The installer can secure the cable-tie to the controller 106 and use on or more clips 105 to secure the controller 106 to the flat back 104. Similarly, like shown in FIG. 3, a user can use the strap hook 108 to secure a coupling device 107 which has a plurality of holes. In this embodiment the strap hook 108 is inserted into one of the holes on the coupling device 107. In one embodiment two clips are positioned on either side of the controller 106. In other embodiments, like that depicted in FIG. 3, a single clip 105 is utilized against an anchor 112. Thus, an installer inserts the anchor 112 into the flat back 104, tightens the coupling device 107 against the controller 106, and then secures the coupling device 107 to the clip 105.

As depicted in FIG. 4, the clip 105 also comprises a strap slot 111. This allows the clip 105 to function as an anchor. A strap can be inserted through the slot 111, pulled taught, and then secured at either that clip 105, a separate clip, or an anchor.

The clip 105 in FIG. 4 also depicts a shelf side 110. This is a planar surface upon which a controller can rest. In this embodiment, rather than being secured only via the coupling device, the controller 106 sits upon the shelf 110 of the clip 105.

While a clip 105 in one embodiment has been described, other clips and accessories can be utilized in the flat rack 104 which allow controllers 106 of various sizes, dimensions, and weights, to be properly secured to the flat rack 104.

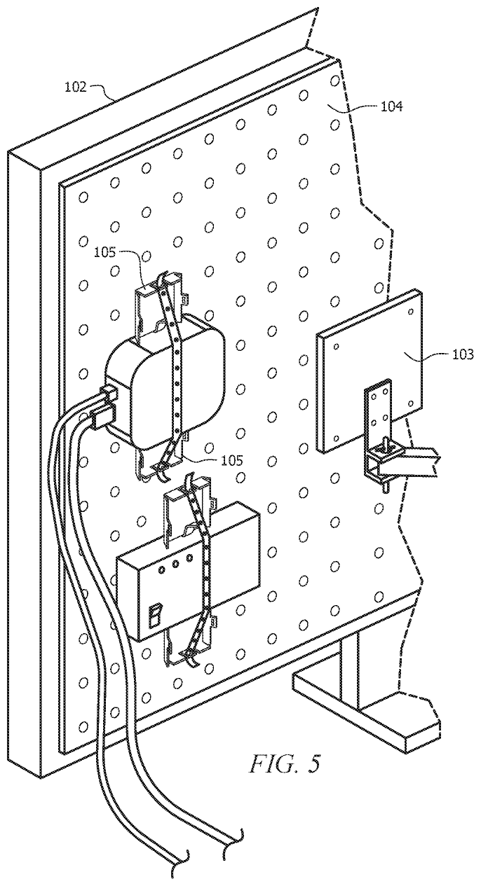

FIG. 5 is a perspective view of a de-centralized system in one embodiment. As shown the mount 103 is coupled to the flat rack 104. Downstream of the flat rack 104 is a television. Two separate controllers 106 are adhered to the flat rack 104 via a plurality of clips 105. The device is sandwiched between an upper and lower clip. As noted, however, an anchor 112 can also be used. An anchor uses friction, diameter width, and/or geometry to secure itself to the holes in the flat rack 104.

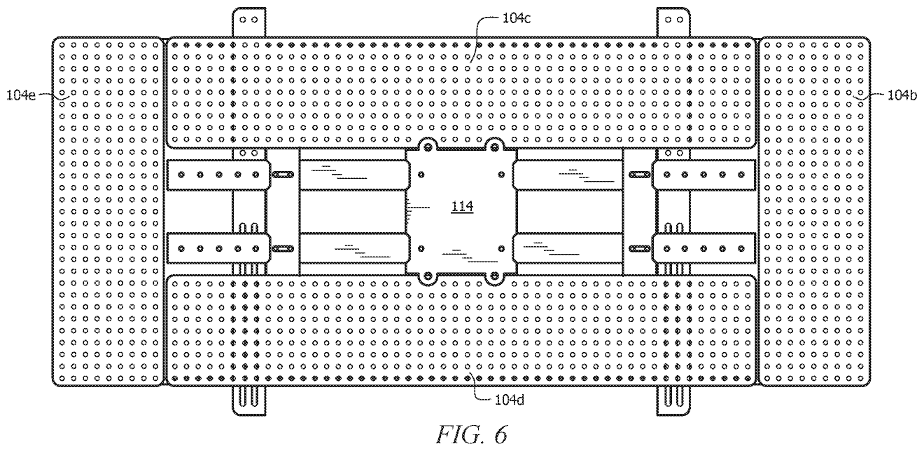

FIG. 6 is a perspective view of an extender in one embodiment. An extender 114 is a device which couples two or more flat racks 104 together. As shown, the extender 114 is coupling an upper portion 104c, the right portion 104b, the left portion 104c, and the lower portion 104d to the extender 114. This allows for larger surface area even when using smaller flat racks 104. In one embodiment, and as depicted, the extender 114 is variable such that the height and/or width can be adjusted. This allows a single extender to function for a variety of different sized situations, televisions, etc.

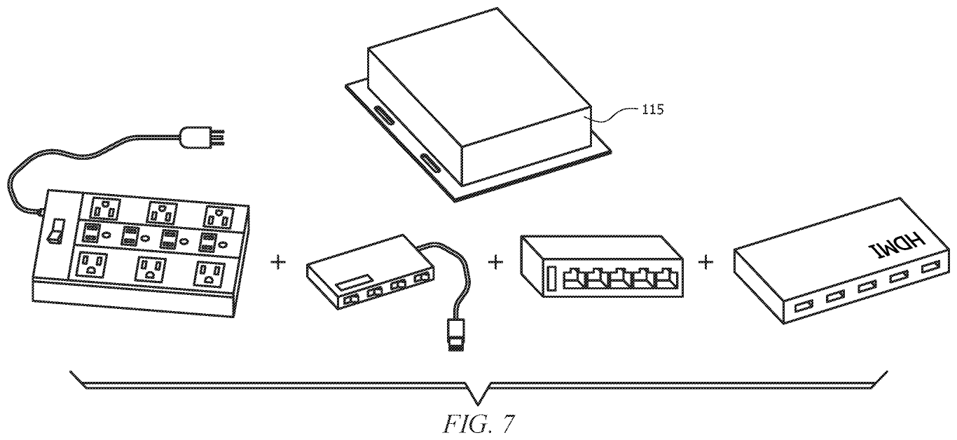

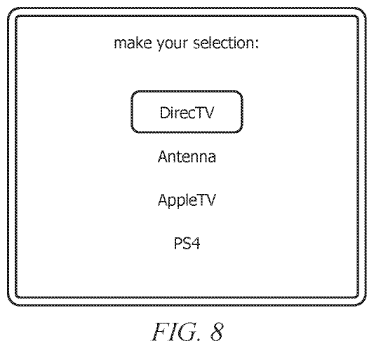

FIG. 7 is a perspective view of the aggregator in one embodiment. The aggregator 115 is hardware which comprise software which allows two or more inputs to be controlled and switched. As noted, the controllers can comprise electronic devices such as DVD players, AppleTv's, etc. which provide a source, such as audio, video, data, etc. In one embodiment, the aggregator 115 receives a signal from one or more controllers 106 and allows the user to select which source to depict via a user interface. Such an interface is depicted in FIG. 8. The user would be able to select, via a user interface associated with software, between DirectTV, antenna, DVD players, etc. In one embodiment the user interface allows the selection of a specific input without any external mechanical change or switch. Instead, the selection takes place via the software and the hardware in the aggregator 115.

Turning back to FIG. 7, in one embodiment the aggregator 115 serves several functions of the devices shown in FIG. 7. The aggregator 115 can serve as a power strip, an adaptor, converter, data ports, HDMI ports, etc. Thus, in one embodiment the aggregator 115 has several input and output ports which allow communication with the television.

The system discussed herein has a plurality of benefits and advantages over the prior art. First, because the system, in one embodiment, is de-centralized, the requirement of a central server rack or closet is eliminated. This allows home builders, for example, to eliminate this closet. Additionally, if such a closet already exits, it allows the home owner, for example, to utilize the closet for other purposes.

Additionally, because the system is not centralized, there is no need to wire the entire house or building with access to a centralized closet. Instead, the controller 106 is located next to the device 102, eliminating the need to string wire throughout the house.

An additional benefit is ease of installation. The controller 106 is securely and compactly stored adjacent to the device 102.

An additional benefit is the lack of visible controllers 106. There is a trend where users want to hide controllers 106 and the wires that are often used to couple them to the device 102. The system discussed herein allows the controllers 106 and/or cable or wiring to be hidden at the flat rack 104. The wires and controllers are hidden from plain view.

An additional benefit is the ability to house a plurality of controllers 106. Televisions, for example, often have several controllers 106. These can include, but are not limited to, cable boxes, DVD players, smart features such as an Apple TV, etc. All of these controllers can be housed 106 at the flat rack 104. Furthermore, controllers 106 for devices other than the television can be housed at the flat rack 104. As an example, wireless routers, WIFI boosters, wireless access points, and other wireless and internet equipment can be stored on the flat rack 104. While these would often be stored along a wall, in a TV stand, or other location, these can now be stored at the flat rack 104.

Another benefit is the ability to eliminate a TV stand. Typically the cable box, DVD player, etc. are stored on a TV stand. Even if the TV is mounted on a wall, the TV stand houses the controllers. This system allows the TV stand to be eliminated.

In one embodiment the system comprises a plurality of speakers in a house, room, or business. In one embodiment the plurality of speakers are wireless. This provides for wireless streaming sound systems which require no centralized amplifier.

While the invention has been particularly shown and described with reference to a preferred embodiment, it will be understood by those skilled in the art that various changes in form and detail may be made therein without departing from the spirit and scope of the invention.

What is claimed is:

1. A system for a de-centralized electronic system comprising:
a flat rack comprising a plurality of holes;
at least one clip for coupling to said flat rack;
a coupling device which couples with said at least one clip.

2. The system of claim 1 further comprising a controller removeably coupled to said flat rack via said clip and said coupling device.

3. The system of claim 1 wherein said flat rack is coupled to a television.

4. The system of claim 3 wherein said flat rack is coupled behind said television.

5. The system of claim 1 wherein said flat rack comprises a plurality of modular pieces.

6. The system of claim 1 wherein said clip comprises at least one leg, wherein said at least one leg extends downward from said clip.

7. The system of claim 1 wherein said clip comprises a shelf side for supporting a controller.

8. The system of claim 1 wherein said clip comprises a cable-tie acceptor.

9. The system of claim 1 wherein said clip comprises a strap slot for receiving a strap.

10. The system of claim 1 wherein said clip comprises a planar base, wherein at least one leg extends downward from said planar base, and wherein said clip comprises at least two functional sides.

11. The system of claim 1 further comprising an extender, wherein said extender couples at least two flat racks together.

12. The system of claim 1 wherein said extender is adjustable.

13. The system of claim 1 further comprising an aggregator.

14. The system of claim 1 comprising two or more controllers and at least one aggregator.
